(19) United States
(12) Patent Application Publication
(10) Pub. No.: US 2015/0064483 A1
(43) Pub. Date: Mar. 5, 2015

(54) METAL DEPOSITION USING ORGANIC VAPOR PHASE DEPOSITION (VPD) SYSTEM

(71) Applicant: University of Southern California, Los Angeles, CA (US)

(72) Inventors: Mark E. Thompson, Anaheim, CA (US); Francisco F. Navarro, Los Angeles, CA (US)

(21) Appl. No.: 14/476,058

(22) Filed: Sep. 3, 2014

Related U.S. Application Data
(60) Provisional application No. 61/872,872, filed on Sep. 3, 2013.

(51) Int. Cl. C23C 14/24; C22C 24/00; C22C 20/00; C22C 23/00; C22C 18/00; H01L 51/00; C22C 28/00; C22C 22/00; C22C 5/06; C22C 21/00; C22C 13/00; C22C 11/00; C23C 14/14; C22C 12/00

(52) U.S. Cl. CPC C23C 14/24; C23C 14/14; C22C 24/00; C22C 20/00; C22C 23/00; C22C 18/00; C22C 12/00; C22C 28/00; C22C 22/00; C22C 5/06; C22C 21/00; C22C 13/00; C22C 11/00; H01L 51/0021
USPC 428/457; 427/252; 420/415; 420/525; 420/402; 420/513; 420/576; 420/577; 420/555; 420/434; 420/501; 420/528; 420/557; 420/563

(57) ABSTRACT

A method of depositing a film of a metal having a volatilization temperature higher than 350° C., as well as, a composite material including the same are disclosed. The method can include providing the source material in a vacuum deposition processing chamber, and providing a substrate in the vacuum deposition processing chamber. The substrate can be spaced apart from, but in fluid communication with, the source material, and also maintained at a substrate temperature that is lower than the volatilization temperature. The method can also include reducing an internal pressure of the vacuum deposition processing chamber to a pressure between 0.1 and 14,000 pascals; volatilizing the source material into a volatilized metal by heating the source material to a first temperature that is higher than the volatilization temperature; and transporting the volatilized metal to the substrate using a heated carrier gas, whereby the volatilized metal deposits on the substrate and forms the metal film.

### CROSS-REFERENCE TO RELATED APPLICATIONS

This application is a non-provisional claiming priority to U.S. Provisional Patent Application Ser. No. 61/872,872, filed Sep. 3, 2013, the entire content of which is incorporated herein by reference.

### PARTIES TO A JOINT RESEARCH AGREEMENT

The claimed invention was made by, on behalf of, and/or in connection with one or more of the following parties to a joint university corporation research agreement: Regents of the University of Michigan, Princeton University, University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to vapor phase deposition of metals.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

In modern optoelectronic applications, the ability to deposit uniform, thin films of metals is important. The most commonly used techniques to deposit metal films are electrodeposition and physical vapor deposition (PVD). Among PVD techniques, vacuum thermal evaporation (VTE), a high vacuum method, is extensively utilized to deposit thin metal films for organic light emitting diodes (OLEDs), organic photovoltaics (OPVs) and thin film transistors (TFTs). The disadvantages of high vacuum methods are long pump down times needed to achieve high vacuum (i.e., ≦10⁻⁵ torr), inefficient utilization of materials, poor film conformality and the high expense incurred when deposition is applied on large substrates. High vacuum is required to achieve long mean free paths and thereby allow the metal atoms to reach the substrate without colliding, which is necessary to produce uniform films. However, deposition using VTE occurs along a directional line-of-sight trajectory preventing the formation of conformal films on nonuniform substrates. Therefore, interest has developed towards non-line-of-sight deposition techniques such as chemical vapor deposition (CVD) and atomic layer deposition (ALD).

Other methods to deposit metals at low pressure (10⁻³-760 torr), such as sputtering, metal-organic chemical vapor deposition (MOCVD) or atomic layer deposition (ALD), have limitations that make them unsuitable for some applications. Sputtering relies on plasma to produce charged ions and high speed electrons that can potentially damage organic thin films, such as those used in OLEDs. MOCVD requires a hot substrate (≦100° C.) in order to decompose the metal-organic precursor and produce a thin metal film. The heated substrate will, in turn, disrupt morphology of preexisting organic films, particularly in multilayer heterostructures. Further, MOCVD can cause organic contamination, also known as parasitic deposition, during the decomposition of the metal-organic compound. ALD typically requires the successive application of precursor compounds in the gas phase, necessitating lengthy growth times for thicker films such as those needed for OLEDs, OPVs and TFTs (1-2 hr for 100 nm films). In addition, ALD requires high substrate temperatures (≧100° C.) to promote the successive reactions on the substrate surface to deposit metals, which also degrades organic films and/or causes parasitic deposition.

Since its inception from 1995 to date, organic vapor phase deposition (OVPD) has been used to make organic thin films. Specifically, OVPD was designed for organic materials that have low sublimation temperatures. Upon sublimation, the material is transported by an inert carrier gas through a vessel with heated walls to avoid unwanted deposition prior to condensation on a cooled substrate, thereby achieving high material utilization (i.e., low waste). The rate at which the material sublimes and ultimately condenses onto the substrate is controlled by both the temperature of the source boat and the flow rate of the inert gas, which enhances control over the deposition process and the morphology of the films. However, while VPD processes have been used to deposit molecular organic materials, forming high efficiency OLEDs, OPVs and TFTs, the method has not been used for the deposition of metal films in optoelectronic devices or otherwise.

### SUMMARY OF THE INVENTION

According to an embodiment, a method of depositing a film of a metallic material having a volatilization temperature higher than 350° C. from a source material is provided. The method can include providing the source material in a vacuum deposition processing chamber, the vacuum deposition processing chamber having an internal pressure, and providing a substrate in the vacuum deposition processing chamber, the substrate being maintained at a substrate temperature that is lower than the volatilization temperature and being spaced apart from, but in fluid communication with, said source material. The method can also include reducing an internal pressure of the vacuum deposition processing chamber to a pressure between 0.1 and 14,000 pascals; volatilizing the source material into a volatilized metal by heating the source material to a first temperature that is higher than the volatilization temperature; and transporting said volatilized metal to said substrate using a heated carrier gas, whereby the volatilized metal deposits on the substrate and forms the metal film.

According to another embodiment, a composite material that includes a substrate having an upper surface; and a metal coating over the upper surface is provided. The metal coating can be formed using a method of depositing a film of a metallic material having a volatilization temperature higher than 350° C. from a source material as described herein.

### BRIEF DESCRIPTION OF THE DRAWINGS

FIG. 1 shows an organic light emitting device, which may be fabricated in whole or in part using the methods described herein.

FIG. 2 shows an inverted organic light emitting device that does not have a separate electron transport layer, which may be fabricated in whole or in part using the methods described herein.

FIG. 3 is a flow chart showing one embodiment of the method described herein.

FIG. 4 is a schematic of a vapor phase deposition (VPD) chamber according to one embodiment, where all source boats are in zone A.

FIG. 5 is a schematic of a vapor phase deposition (VPD) chamber according to one embodiment, where all source boats are in zone B.

FIG. 6 is a schematic of a vapor phase deposition (VPD) chamber according to one embodiment, where some source boats are in zone A, while others are in zone B.

FIG. 7 is a close-up schematic of carrier gas and volatilized metal passing through the exit nozzle of the source tube toward the substrate.

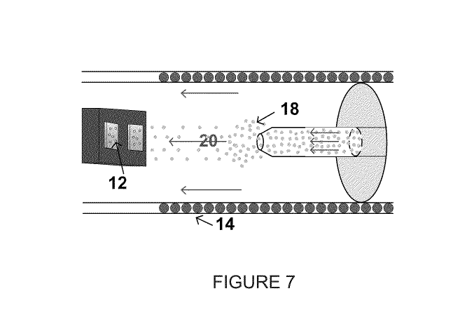

FIG. 8 is a cross-sectional view of a substrate with a metal film deposited thereon.

FIG. 9 is an example OLED configuration.

FIG. 10 is a graph of external quantum efficiency (%) of an OLED made using VPD methods as described herein.

FIG. 11 is a graph of brightness (cd/m2) of an OLED made using VPD methods as described herein.

FIG. 12 is a graph of external quantum efficiency (%) of a comparative OLED made using a VTE method.

FIG. 13 is a graph of brightness (cd/m2) of a comparative OLED made using a VTE method.

FIG. 14 is an example OPV configuration.

FIG. 15 is a graph of current-voltage (IV) curves for an OPV made using VPD methods as described herein.

FIG. 16 is a graph of external quantum efficiency (%) for an OPV made using VPD methods as described herein.

FIG. 17 is a graph of current-voltage (IV) curves for a comparative OPV made using a VTE method.

FIG. 18 is a graph of external quantum efficiency (%) for a comparative OPV made using a VTE method.

FIG. 19 shows cross-sectional SEM images of a 200 nm magnesium film deposited of a silicon substrate using VPD (top) and VTE (bottom), where the VPD film was deposited at a substrate temperature of 20-25° C.

FIG. 20 shows three-dimensional atomic force microscopy (AFM) images of 200 nm magnesium films deposited on a silicon substrate using both VPD (top) and VTE (bottom).

FIG. 21 is a graph showing XRD patterns of 200 nm magnesium (Mg) films deposited on a silicon substrate using VPD (top) and VTE (bottom), with the vertical lines representing reference crystal planes of the hexagonal phase of Mg.

FIGS. 22(A) and (B) are graphs of external quantum efficiency/brightness versus voltage characteristics of (a) fluorescent Alq3, and (b) phosphorescent Ir(ppy)3 OLEDs, with current density vs voltage characteristics shown in the inset.

FIG. 23 is a graphs showing current versus voltage (IV) curves of CuPc/C₆₀/PTCBI/Mg OPVs formed using VPD and VTE, with external quantum efficiency (%) data shown in the inset.

### DETAILED DESCRIPTION

Common deposition systems used for making thin metal films include vacuum thermal evaporation (VTE), sputtering, electron beam physical vacuum deposition (EBPVD) and metalorganic chemical vapor deposition (MOCVD) systems. These technique operate at very low pressures (<0.001 Pa), are wasteful because they deposit metal on the apparatus itself, and/or are not compatible with organic light emitting diodes (OLEDs) and organic photovoltaics (OPVs) because they damage the underlying organic layers (e.g., ion bombardment). Despite the anticipated difficulties, after much research and refinement, a modified VPD technique has been developed that eliminates these issues and produces a electrode with desirable properties. It was surprisingly discovered that by maintaining a very low substrate temperature, it was possible to produce useful metal film using the techniques described herein.

The VPD technique described herein can be used to make OLED and OPV devices. Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton.” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75. No. 3, 4-6 (1999) (“Baldo-II”), which are incorporated by reference in their entireties. Phosphorescence is described in more detail in U.S. Pat. No. 7,279,704 at cols. 5-6, which are incorporated by reference.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

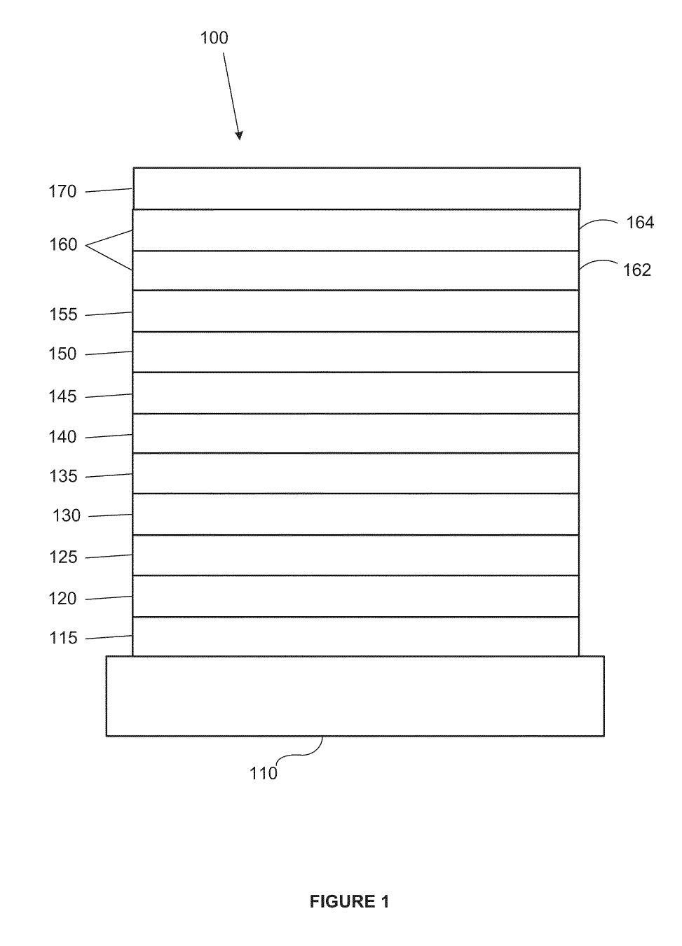

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of a metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

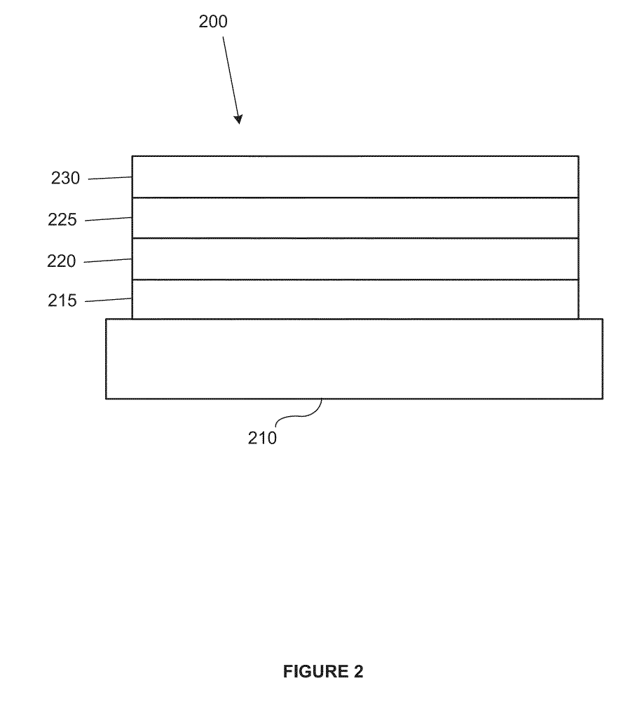

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

OLED devices fabricated in accordance with embodiments of the invention may be incorporated into a wide variety of consumer products, including flat panel displays, computer monitors, medical monitors, televisions, billboards, lights for interior or exterior illumination and/or signaling, heads up displays, fully transparent displays, flexible displays, laser printers, telephones, cell phones, personal digital assistants (PDAs), laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 degrees C. to 30 degrees C., and more preferably at room temperature (20-25 degrees C.), but could be used outside this temperature range, for example, from −40 degree C. to +80 degree C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

According to one embodiment, a method 300 of depositing a film of a metallic material having a volatilization temperature higher than 350° C. is described. As used herein, “volatilization temperature” refers to a temperature that produces a metal vapor from a source material and can refer to either a sublimation temperature or a boiling temperature.

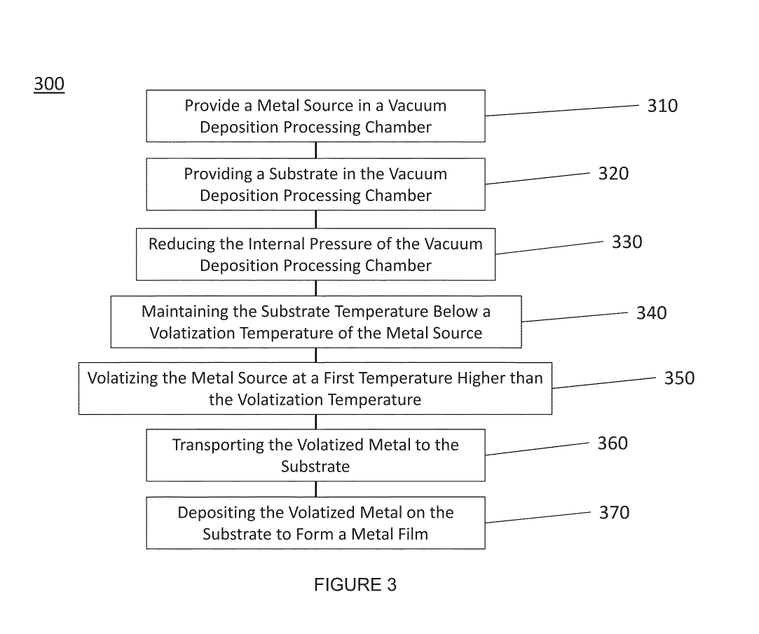

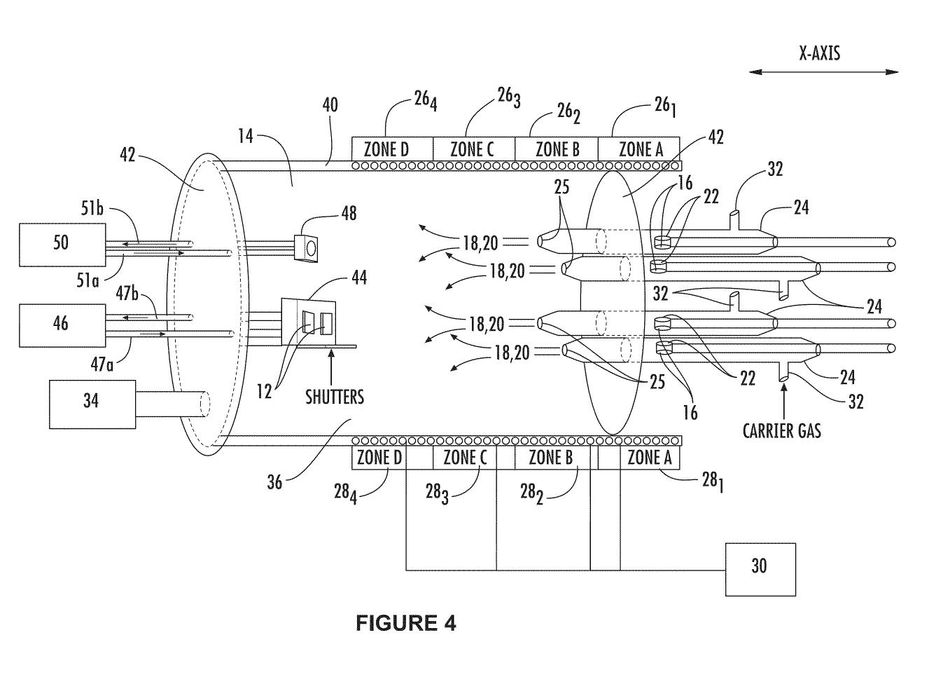

As shown in FIG. 3, the method can include a step 310 that involves providing a source material 12 in a vacuum deposition processing chamber 14, where the vacuum deposition processing chamber 14 has an internal pressure. Examples of vacuum deposition processing chambers 14 useful for the methods described herein are shown in FIGS. 4-6.

Step 320 of the method can include providing a substrate 12 in the vacuum deposition processing chamber 14, wherein the substrate 12 is spaced apart from, but in fluid communication with, the source material 16. According to step 330, the method can include reducing an internal pressure of the vacuum deposition processing chamber 14 to a pressure ranging from 0.1 and 14,000 pascals. In some embodiments, the internal pressure of the vacuum deposition processing chamber 14 is greater than 1 Pa, or greater than 10 Pa, or greater than 25 Pa, or greater than 50 Pa, or greater than 75 Pa, or greater than 100 Pa. In some embodiments, the internal pressure of the vacuum deposition processing chamber 14 is less than 14,000 Pa, or less than 10,000 Pa, or less than 5,000 Pa, or less than 2,500 Pa, or less than 1,000 Pa.

The method can include step 340, which requires maintaining the substrate 12 at a substrate temperature that is lower than the volatilization temperature of the source material 16. Step 350 involves volatilizing the source material 16 to produce a volatilized metal 18 by heating the source material 16 to a first temperature that is higher than the volatilization temperature of the source material. As used herein, “volatilized metal” relates to metal atoms and aggregates of metal atoms in the vapor phase. In step 360, the volatilized metal 18 is transported to the substrate using a heated carrier gas 20. The method also includes depositing the volatilized metal 18 on the substrate 12 to form a metal film 36 in step 370.

In some embodiments, the substrate 12 is maintained at a substrate temperature in the range of −100° C. to 200° C. In some embodiments, the substrate 12 is maintained at a temperature in the range of −40° C. to 140° C. In some embodiments, the substrate 12 is maintained at a temperature in the range of −20° C. to 130° C. This helps facilitate deposition of the volatilized metal 18 on the substrate 12, as well as, preventing damage to any underlying layers also deposited over the substrate 12.

As will be understood, while the steps of the method are described in a particular sequence, some of the steps can be performed in different orders, while others will occur simultaneously. For example, in some embodiments, the substrate can be provided prior to providing the source material. In some embodiments, significant portions of steps 330 through 370 will occur simultaneously as part of a deposition process, even though steps 33- through 370 may be initiated at different times and in different orders.

In some embodiments, the substrate holder 44 is coupled to a substrate cooling system 46, which may include a cooling line 47a and a return line 47b. In some embodiments, the substrate cooling system 46 can use a cooling medium such as, but not limited to, water, water/ethylene glycol mixtures, chlorofluorocarbons, fluorocarbons, hydrofluorocarbons, cooled gases (e.g., nitrogen, carbon dioxide, helium), and liquid gases (e.g., liquid nitrogen, liquid carbon dioxide). In some embodiments, the substrate cooling system 46 can utilize a cooling medium that can be cooled to a temperature of −100° C. or less, or −125° C. or less, or −150° C. or less, or −175° C. or less, or −185° C. or less. For example, in one embodiment, the cooling medium can be nitrogen gas cooled to −185° C.

In some embodiments, the system can also include a crystal monitor 48 capable of monitoring the thickness of the metal film 36 being deposited on the substrate 12. The crystal monitor 48 can be coupled to a crystal monitor cooling system 50, which may include a cooling line 51a and a return line 51b. In some embodiments, the crystal monitor cooling system 48 can use a cooling medium such as, but not limited to, water, water/ethylene glycol mixtures, chlorofluorocarbons, fluorocarbons, hydrofluorocarbons, cooled gases (e.g., nitrogen, carbon dioxide, helium), and liquid gases (e.g., liquid nitrogen, liquid carbon dioxide). In some embodiments, the crystal monitor cooling system 48 can utilize a cooling medium that can be cooled to a temperature of −100° C. or less, or −125° C. or less, or −150° C. or less, or −175° C. or less, or −185° C. or less. For example, in one embodiment, the cooling medium can be nitrogen gas cooled to −185° C. In some embodiments, the substrate cooling system 46 and the crystal monitor cooling system 50 can be a single cooling system. Examples of chlorofluorocarbons, fluorocarbons, and hydrofluorocarbons useful in the cooling systems 46, 50 described herein include those sold under the mark FREON by E. I. du Pont de Nemours and Company (Wilmington, Del.).

In some embodiments, the source material 16 includes a metallic material selected from the group consisting of calcium, cadmium, magnesium, zinc, antimony, bismuth, indium, manganese, silver, aluminum, tin, lead, and alloys thereof. In some embodiments, the source material 16 consists of metallic material only (i.e., no organic components). In some embodiments, the source material 16 can be a pure metal selected from the group consisting of calcium, cadmium, magnesium, zinc, antimony, bismuth, indium, manganese, silver, aluminum, tin, and lead. In other embodiments, the source material 16 can be an alloy selected from a combination of at least two of metals selected from the group consisting of calcium, cadmium, magnesium, zinc, antimony, bismuth, indium, manganese, silver, aluminum, tin, and lead. In some embodiments, the source material 16 is Mg or Zn. As used herein, the term “alloy” has its ordinary meaning and includes a homogeneous mixture or solid solution of two or more metals.

In some embodiments, as shown in FIGS. 4-6, the source material 26 can include at least two metallic materials. In such embodiments, the at least two metallic materials can be different pure metals and the resulting metal film 36 can be an alloy of the pure metals. The pure metals can be selected from the group consisting of calcium, cadmium, magnesium, zinc, antimony, bismuth, indium, manganese, silver, aluminum, tin, and lead. For example, in some embodiments, the first metallic material is pure magnesium and the second metallic material is pure zinc, with any additional metallic materials being either pure magnesium or pure zinc.

The walls of the vacuum deposition processing chamber 14 can be made of any material capable of withstanding the operating temperatures and pressures utilized in the vapor phase deposition process described herein. Examples of materials that can be used to form the vacuum deposition processing chamber 14 include, but are not limited to, high temperature metal alloys, borosilicate glass, and fused silica. In some embodiments, the walls of the vacuum deposition processing chamber 14 are formed from a material selected from the group consisting of borosilicate glass and fused silica. Examples of borosilicate glass useful as the walls of the vacuum deposition processing chamber 14 include borosilicate glasses, such as PYREX®, sold by Corning Incorporated.

In some embodiments, as shown in FIGS. 4-6, the vacuum deposition processing chamber can be formed of a tubular body 40 with endcaps 42 at each end of the tubular body 40. In some embodiments, the tubular body 40 can be formed from a material selected from the group consisting of borosilicate glass and fused silica, while the endcaps (or flanges) can be formed of a high temperature metal alloy, such as iron alloys (e.g., steel), nickel alloys, and cobalt alloys.

In some embodiments, the method includes heating the walls of the vacuum deposition chamber. In some embodiments, the method includes heating the longitudinal walls (x-axis) of the vacuum deposition chamber 14. For example, some or all of the tubular body 40 can be heated. The heating helps prevent the volatilized metal 18 from being deposited on the walls of the vacuum deposition chamber.

As shown in FIGS. 4-6, in some embodiments, the vacuum deposition chamber 14 comprises a first zone (e.g., zone A or B) and a second zone (e.g., zone D), where the second zone is closer to the substrate 12 than the first zone. In such embodiments, the method can include maintaining the first zone (e.g., zone A or B) at the first temperature, which is higher than a second zone temperature of the second zone (e.g., zone D). In some embodiments, during the volatilization step 350, the source material 16 can be positioned in the first zone (e.g., Zone A or B), while the substrate 12 can be positioned in the second zone (e.g., Zone D). In other embodiments, during the volatilization step 350, the source material 16 can be positioned in the first zone (e.g., Zone A or B), while the substrate 12 can be positioned just outside the second zone (e.g., Zone D) in an unheated portion of the vacuum deposition processing chamber 14.

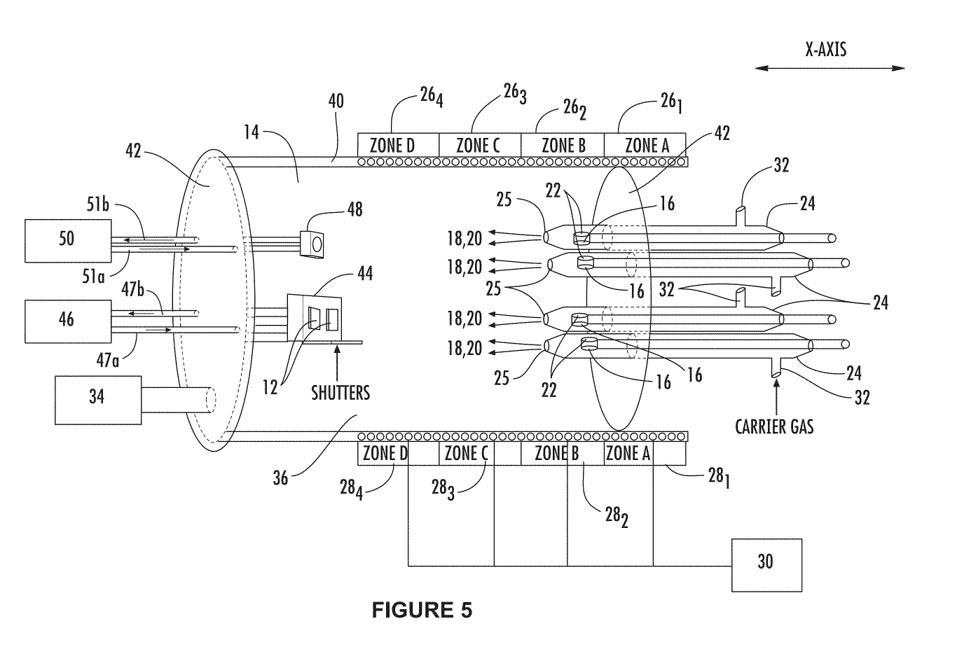

In some embodiments, the vacuum deposition chamber includes an intermediate zone between the first and second zones, where the intermediate zone is maintained as a temperature between the first zone temperature and the second zone temperature. For example, in FIG. 4, zones B and C would be intermediate zones, while only zone C would be an intermediate zone in FIG. 5.

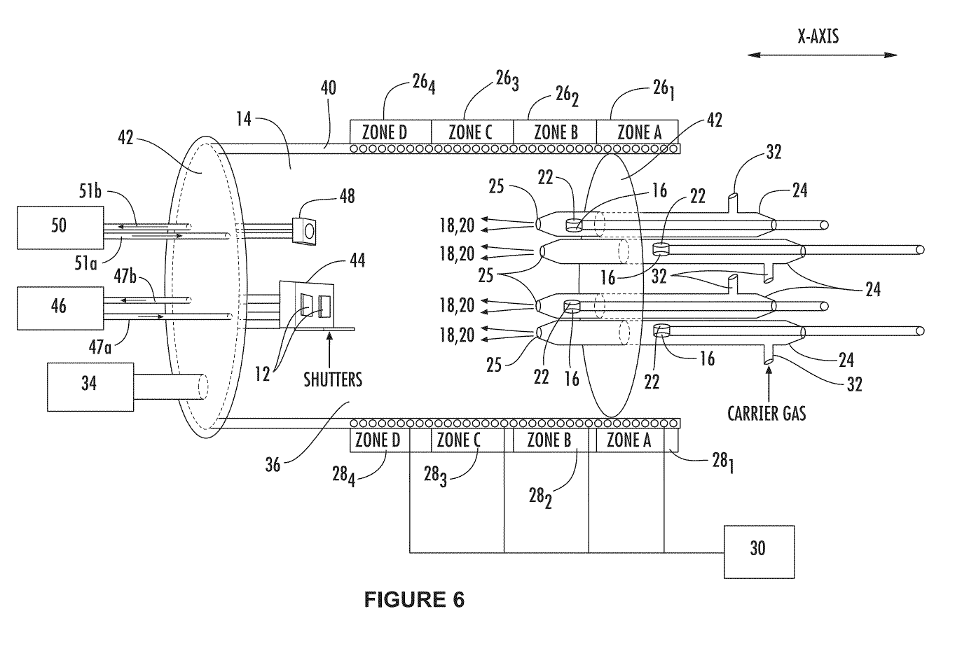

In some embodiments, where the source material 16 includes two different source materials on two different source boats 22, the different source materials may be located in different zones. For example, as shown in FIG. 6, a metal with a higher volatilization temperature may be supported by a source boat 22 located in zone A, while a metal with a lower volatilization temperature may be supported by a source boat 22 located in zone B. In such embodiments, in order to facilitate proper volatilization of both metals, zone A may be maintained at a higher temperature than zone B.

In order to maintain the desired temperature profile, each zone 26₁-26ₙ can include a separate heating element 28₁-28ₙ. Such an arrangement is shown in FIGS. 4-6. In some embodiments, each of the heating elements 28₁-28ₙ can be coupled to and controlled by a controller 30 adapted to provide independent temperature control for each heating element 28₁-28ₙ.

In some embodiments, the volatilizing step 350 is not ion assisted. In other words, in such embodiments, the volatilizing step 350 does not include generating a plasma or exposing the source material to a plasma.

In some embodiments, the carrier gas 20 is nitrogen or another gas that is non-reactive within the vacuum deposition processing chamber 14. Examples of suitable carrier gases include, but are not limited to, nitrogen, helium, argon, helium, carbon dioxide, chlorofluorocarbons, fluorocarbons, hydrofluorocarbons, and hydrogen. In some embodiments, the carrier gas 20 does not react or decompose when passing within the vacuum deposition processing chamber 14 during the process described herein.

In some embodiments, the flow rate of the carrier gas 20 is at least 1 standard cubic centimeters per minute (sccm). In some embodiments, the flow rate of the carrier gas 20 is at least 2 sccm, or at least 3 sccm, or at least 5 sccm, or at least 10 sccm. In some embodiments, the average residence time of the carrier gas 20 within the vacuum deposition processing chamber 14 is less than 3 minutes. In some embodiments, the average residence time of the carrier gas 20 within the vacuum deposition processing chamber 14 is less than 2 minutes, or less than 1 minute, or less than 45 seconds, or less than 30 seconds, or less than 20 seconds.

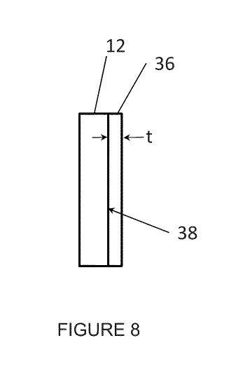

In some embodiments, a rate of metal deposition on the substrate 12 is at least 0.1 Å per second. In some embodiments, a rate of metal deposition on the substrate 12 is at least 0.25 Å per second, or at least 0.5 Å per second, or at least 1 Å per second. As used herein, as shown in FIG. 8, the deposition rate is measured based on the thickness (t) of the film being applied.

According to another aspect of the present disclosure, as shown in FIG. 8, a composite material comprising a substrate 12 having an upper surface 38, and a metal coating 36 over the upper surface 38 is disclosed. The metal coating 36 can be formed using any of the methods or devices described herein. As shown in FIGS. 1 & 2, the composite material can also include an emissive layer coated 135, 220 over the upper surface, where the emissive layer 135, 220 comprises an organic electroluminescent compound and a host. In some embodiments, the metal coating 36 can be an electrode (e.g., 115, 160, 215, 230).

As will be apparent, in some embodiments, one or more layers of materials will already be deposited on the substrate 12 before the metal film 36 is deposited. For example, if the method described herein is used to deposit the upper electrode 160, 230 of the OLEDs in FIGS. 1 & 2, there will be multiple layers, including layers (e.g., emissive layers 135, 220) that include organic materials present in the vacuum deposition processing chamber 14 during VPD deposition of the upper electrode 160,230. It has been determined that is possible to use the method described herein, even where such layers are present, if the substrate 12 is cooled well below 200° C. It has been determined that this prevents or sufficiently limits damage to the organic materials already present on the substrate 12 to produce OLED and OPV devices include upper electrodes formed using the techniques described herein.

In some embodiments, the metal coating 36 can include or consist of a metal selected from the group consisting of calcium, cadmium, magnesium, zinc, antimony, bismuth, indium, manganese, silver, aluminum, tin, lead, and mixtures thereof. In some embodiments, the metal coating 36 can include or consist of magnesium, zinc, or a mixture thereof.

### EXPERIMENTAL

### Study 1

Mg and Zn films were successfully deposited using PVD with a variety of substrate temperatures ranging from −20° C. to 200° C. The color of the metal films varied depending on the substrate temperature and ranged from light grey to shiny silver for temperatures from −20° C. to 200° C., respectively. All metal films were made with pressures spanning from 1 to 1400 pascals, total carrier gas flows ranging from 1 to 300 sccm and deposition rates between 1 to 60 Å/s. Further, all metal films were conductive and viable to use as electrodes in OLEDs and OPVs. By effectively controlling substrate temperature, devices were made for substrate temperatures ranging from −20° C. to 200° C., and even though metal film quality observed at 200° C. suggested devices would work, only devices made with substrate temperatures below <130° C. performed similar to devices made in the VTE. Below, we present examples of OLED and OPV devices fully made in the VPD and VTE. Operating conditions for devices made using VPD are shown in Table 1 and 2. FIG. 4 shows a general schematic of the VPD setup.

TABLE 1
VPD Deposition Conditions
VPD Pressure, Flow and Deposition Rate Conditions

| Total Pressure | Total Carrier Gas | Deposition Rate | Deposition Rate |
|---|---|---|---|
| (Pascals) | Flow (sscm) | of Organics (A/s) | of Metals (A/s) |
| 133.3 | 60 | 2 to 4 | 4 to 8 |

TABLE 2
VPD Deposition Conditions
VPD Gradient Temperature Conditions

| OVPD Settings | | | Metal Setting | | |
|---|---|---|---|---|---|
| Zone 1 | Pre-Substrate | 300° C. | Zone 1 | Pre-Substrate | 450° C. |
| | Zone | | | Zone | |
| Zone 2 | Hot Zone | 350° C. | Zone 2 | Hot Zone | 550° C. |
| Zone 3 | Hot Zone | 350° C. | Zone 3 | Hot Zone | 600° C. |
| Zone 4 | Pre-Heating | 350° C. | Zone 4 | Pre-Heating | 600° C. |
| | Zone | | | Zone | |

### Example 1

### OLEDs Made in the VPD

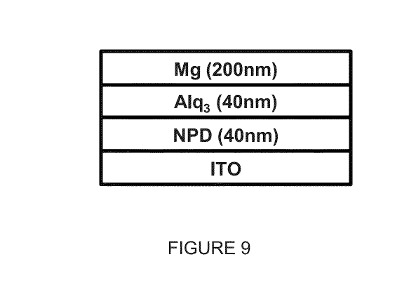

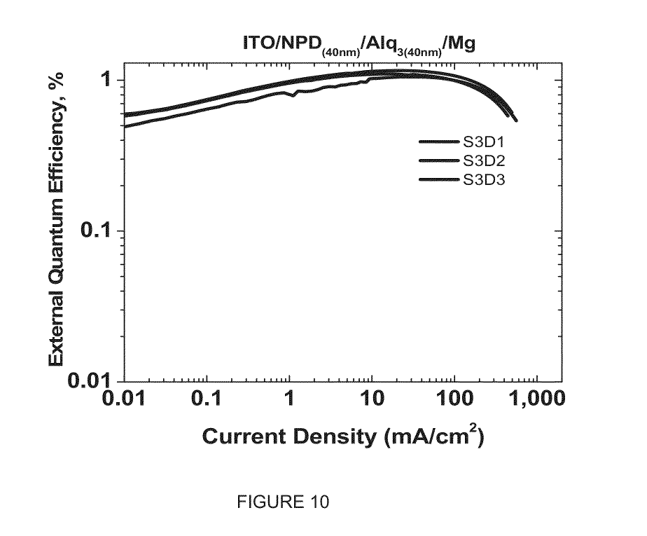

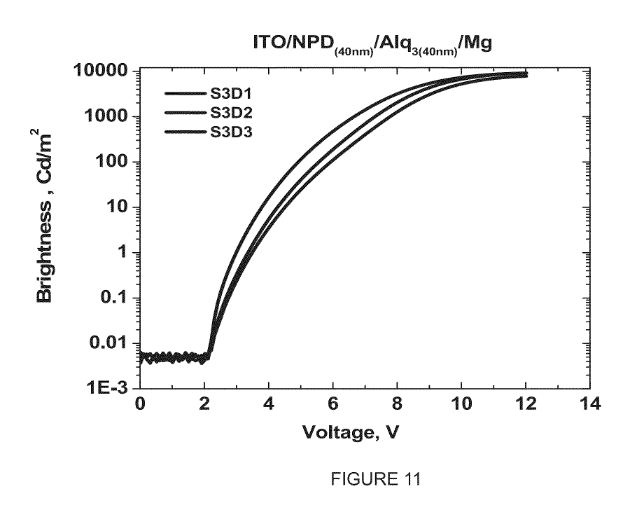

Devices made in the VPD had the structure shown in FIG. 9. The external quantum efficiency and brightness of the device can be observed in FIGS. 10 and 11, respectively.

### Comparative Example 1

### OLEDs Made in the VTE

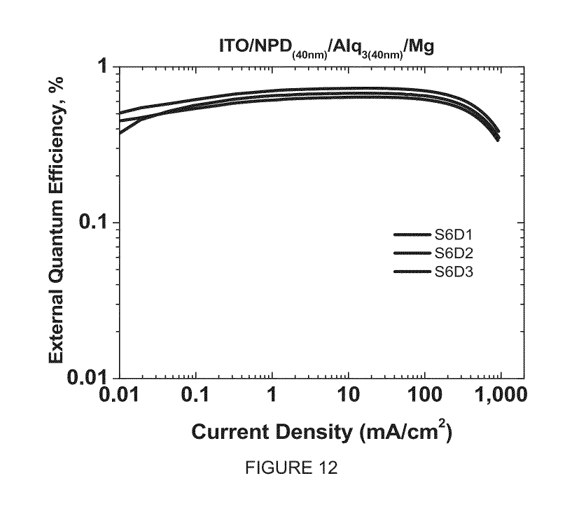

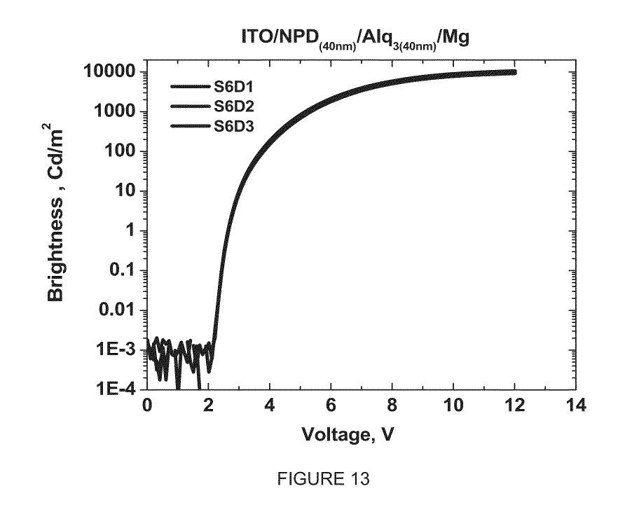

Devices made in the VTE had the structure shown in FIG. 9. The external quantum efficiency and brightness of the device can be observed in FIGS. 12 and 13, respectively. These films were deposited with pressures ≦4×10⁻⁴ pascals and deposition rates between 1 to 5 Å/s.

### Example 2

### OPVs Made in the VPD

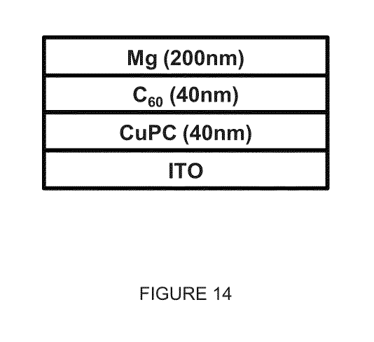

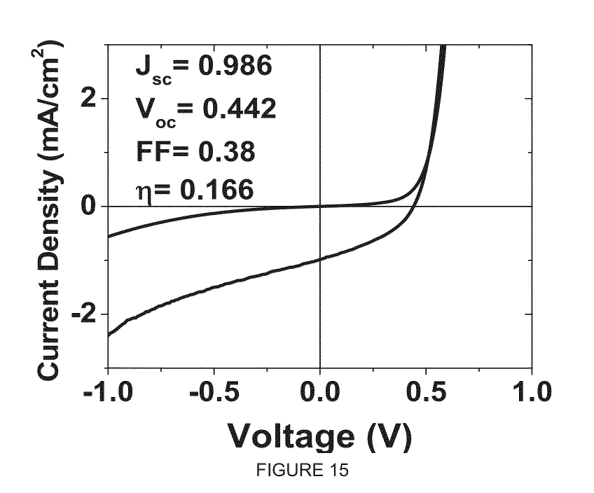

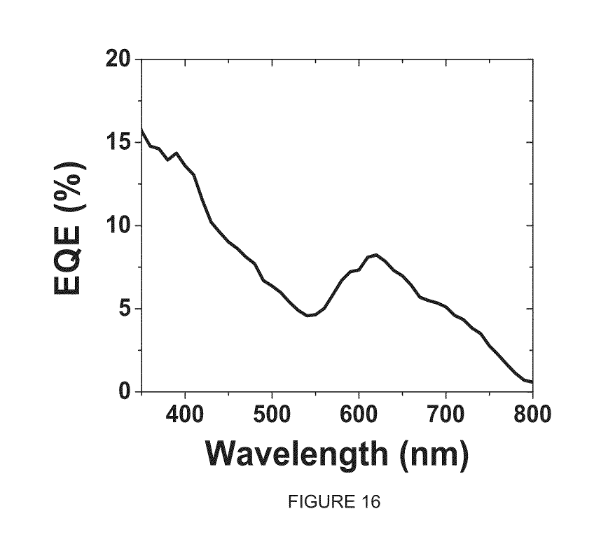

Devices made in the VPD had the structure shown in FIG. 14. Current-Voltage (IV) curves and external quantum efficiency can be seen in FIGS. 15 and 16, respectively. Device efficiency (η), short circuit current (J_{sc}), open circuit voltage (V_{oc}) and fill factor (FF) are also reported in FIG. 15.

### Comparative Example 2

### OPVs Made in the VTE

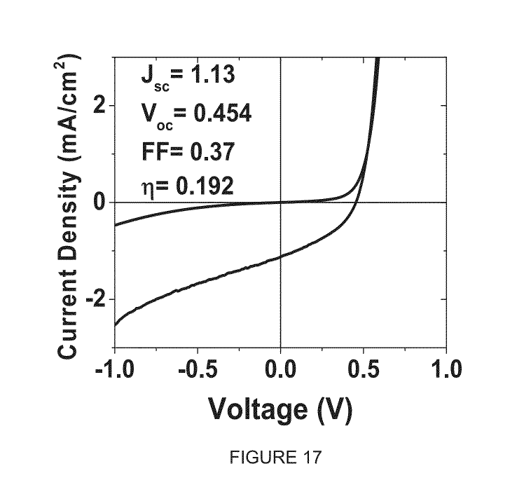

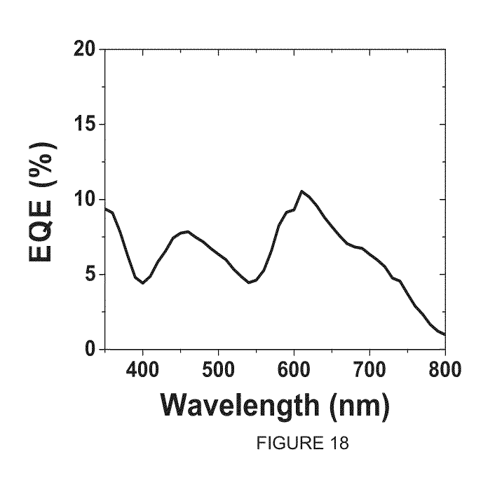

Devices made in the VTE had the structure shown in FIG. 14. Current-Voltage (IV) curves and external quantum efficiency can be seen in FIGS. 17 and 18, respectively. Device efficiency (η), short circuit current (J_{sc}), open circuit voltage (V_{oc}) and fill factor (FF) are also reported in FIG. 17.

### Study 1

### Conclusions

By adequately controlling substrate temperature, it was possible to deposit high sublimation materials, e.g., Mg, Zn, etc. in a VPD system. In addition, OLED and OPV devices were made entirely using VPD techniques. The results show the VPD devices exhibit performance levels similar to devices made using common deposition systems, such as the VTE. If a quartz tube is used instead of a Pyrex tube, materials with higher sublimation temperatures can be employed to make OLEDs and OPVs.

### Study 2

### Deposition Parameters

A series of metals were considered for use in the VPD, including calcium, zinc, cadmium, magnesium, antimony, bismuth, indium and manganese, among others. Of these, magnesium (Mg) and zinc (Zn) were selected to fabricate metal films and devices. Both magnesium and zinc exhibit low toxicity and have been used as electrodes to inject charge into OLEDs. The effective volatility of both metals was evaluated by calculation of molar flow rates (r) using Equation 1 below:

$$r = \dot{V} \cdot \frac{{P}_{org / met}}{{RT}_{cell}} \qquad ( 1 )$$

where \dot{V} is the volumetric flow velocity of the carrier gas, R is the ideal gas constant, T_{cell} is the temperature of the source boat, and P_{org/met} is the vapor pressure of the organic/metal. The calculations show that Mg and Zn can have molar flow rates comparable to values obtained for organics with high sublimation temperatures, such as CuPc (Table 3). In a laminar flow regime, the diffusion of these metals within the carrier gas stream plays an important role in determining the transport efficiency of the material. Diffusion coefficients for Mg and Zn were calculated using the Chapman-Enskog theory (Equation 2):

$$D = \frac{1858 \times {10}^{- 3} {T}^{3 / 2} \sqrt{1 / {M}_{1} + 1 / {M}_{2}}}{p {σ}_{12}^{2} Ω} \qquad ( 2 )$$

where T is temperature, M is the molar mass, p is pressure, Ω is the temperature dependence collision integral, σ₁₂=(σ₁+σ₂)/2 is the average collision diameter, D is the diffusion coefficient, and 1 and 2 are indices for the two molecules present in the gaseous mixture. The calculated results are shown in Table 3. The calculations revealed that the diffusivity of these metals are one order of magnitude greater than values determined for typical OLED and OPV compounds. Such high diffusivities promote metal deposition in various regions of the sample chamber upstream from the source nozzles. These problems can potentially be averted by increasing the total flow of the carrier gas. However, an increase in carrier gas flux can raise the

TABLE 3
Chapman-Enskog diffusion coefficients and sublimation
enthalpies for Zn, Mg, CuPc, Alq₃ and NPD.

| | Enthalpy of | Vapor | Molar flow | Diffusion | Molar | Average |
|---|---|---|---|---|---|---|
| | sublimation | pressure | rate | coefficient | mass | collision |
| Compound | [KJ/mol]^{a,b,c} | [atm]^{b,d,}* | [mol/s] | [cm²/s] | [g/mol] | diameter [Å]^{¥} |
| nitrogen | — | — | — | — | 28.0 | 4.2 |
| zinc | 130.4 ± 0.4^{a} | 7.4E−03^{d} | 8.0E−01 | 614.7 | 65.4 | 2.8 |
| magnesium | 147.1 ± 0.8^{a} | 3.9E−04^{d} | 4.2E−02 | 497.6 | 24.3 | 4.4 |
| CuPc | 211.1 ± 0.1^{b} | 1.7E−03^{b} | 1.8E−01 | 51.9 | 576.1 | 18.1 |
| Alq₃ | 137.7 ± 0.1^{b} | 1.1E−04^{b} | 1.5E−02 | 45.5 | 459.4 | 15.2 |
| NPD | 139.0 ± 0.3^{c} | — | — | 23.7 | 588.7 | 22.6 |

*Temperatures used to calculate vapor pressures of Zn, Mg, and CuPc, was 823 K and 623 K for Alq₃ and NPD.
^{¥}Average collision diameter, σ₁: N₂ and σ₂: Zn, Mg, CuPc, Alq₃ and NPD were measured using Titan 1.0.7 software (diameters have Van der Waals radii integrated).
Calculations of molar flow rates and diffusion coefficients were performed at a pressure of 1 torr. The collision integral (Ω) was taken as unity given that it has values between 0.96 and 1.03 for temperatures between 300 K and 1000 K.
^{a}W. Plieth (2008), Electrochemistry for Materials Science. Oxford, UK: Elsevier
^{b}K. Yase, Y. Takahashi, N. Ara-Kato & A. Kawazu. Jpn. J. Appl. Phys. 34, 636 (1995)
^{c}Shtein, M. Gossenberger, H. F.; Benziger, J. B.; Forrest, S. R. J. Appl. Phys. 89, 1470 (2001)
^{d}CRC Handbook of Chemistry and Physics, 94th Edition, 2013-2014. www.bbcpnetbase.com (accessed Dec. 12, 2013)

operating pressure if the pumping system is not suitable for large flows, thus affecting film morphology and crystallinity. In our system, condensation was observed upstream on the rear flange of the VPD chamber when the pump did not maintain a pressure of 1 torr in flows exceeding 60 standard cubic centimeters per minute (sccm). The inability to pump at a higher velocity necessitated a modification in the deposition apparatus by inserting a fused silica wall around the source tubes between zone A and zone B of the system seen in FIG. 4. In particular, the fused silica wall prevents deposition of materials in the relatively cool zones upstream (i.e., furthest from the substrate) of the nozzle tips. This fused silica wall is unnecessary when depositing materials with low diffusivity, such as organic compounds.

During the sublimation of Mg and Zn, the VPD chamber was kept at 450° C. (zone D) and 550° C. (zones A-C) to prevent the metals from condensing on the chamber walls. However, metals such as Mg and Zn exhibit high surface mobility and poor wettability, a problem that can be correlated to the critical density and critical temperature of the metals. The critical density is a measure of the number of atoms striking 1 cm²/s needed to achieve condensation on a substrate and is directly related to the substrate temperature, whereas the critical temperature is reached when the probability of an atom condensing on the substrate is unity. The high temperatures in the VPD chamber, along with the high surface mobility and poor wettability of Mg and Zn on a hot substrate, requires efficient cooling to produce high quality films. Therefore, a liquid-cooled substrate holder was built using aluminum (thermal conductivity=220 W/mK) in order to maintain adequate control of the substrate temperature. In addition, during initial attempts at fabricating metal films it was determined that a water/ethylene glycol (50/50) mixture cooled at −20° C. was incapable of keeping the substrate below 120° C. While this temperature was sufficient to promote metal deposition, the organic films were not stable at these temperatures. Thus, the cooling medium was switched to N₂ gas cooled to −185° C. This last modification made it possible to reliably maintain substrate temperatures below 50° C. during metal deposition, and thereby prepare good quality OLEDs and OPVs (see below).

The above modifications to the VPD chamber (fused Pyrex wall) and cooling system gave deposition rates of 0.1-35.0 Å/s and facilitated production of metal films with thicknesses ranging from 100 to 10,000 nm. However, the elevated temperature of the system during metal deposition caused organics previously condensed on the shutters to sublime, leading to cross contamination during fabrication of the cathode and subsequent device failure. To overcome this obstacle and avoid cross-contamination with organics during the fabrication of the cathode, the shutters were cleaned prior to deposition of the metal.

### Magnesium and Zinc Metal Films

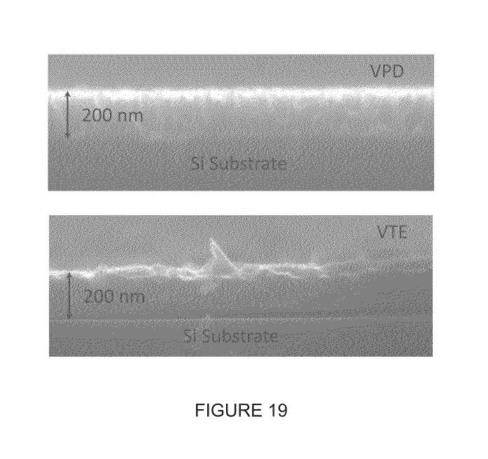

For comparative purposes, thin films of Mg and Zn were fabricated in both VPD and VTE systems on silicon and patterned indium tin oxide (ITO). Metal films were deposited at rates ranging from 4-8 Å/s and for VPD films, using substrate holder temperatures of 20-25° C., and total flows of 60 sccm. Metal films made by both methods were reflective and glossy. Calibration of the quartz crystal monitor sensor for Mg and Zn films, deposited in the VPD on patterned ITO was accomplished using profilometry. The Mg and Zn films were analyzed to determine their morphology, roughness, crystallinity and resistivity. Cross-sectional SEM images of Mg films deposited on silicon substrates using VPD and VTE (FIG. 19) show complete substrate coverage and a crystalline, rough surface morphology. Films made using VPD display a loose packing of blade-like nanocrystals whereas films made using VTE are more densely packed.

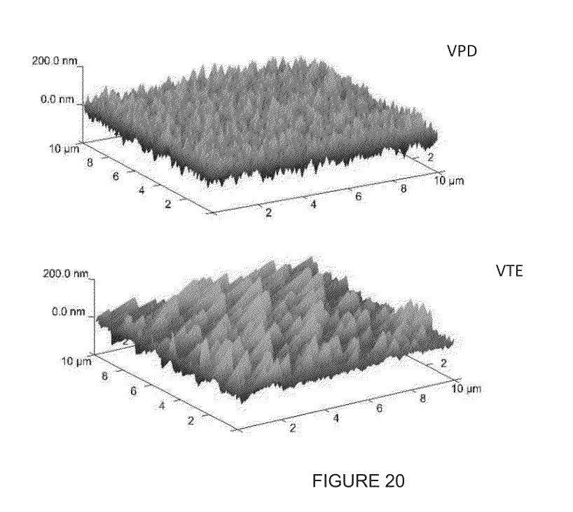

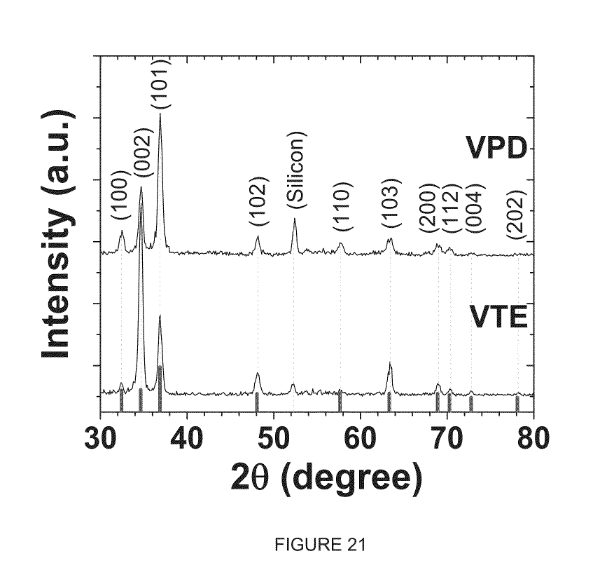

Three-dimensional AFM images (FIG. 20) confirmed the results showing both films exhibit full substrate coverage and a rough surface texture. However, while the SEM and AFM images of the VTE film appeared to have higher peak-to-valley aspect ratios than the VPD film, the average film roughness/uniformity of both films is similar (RMS values for VPD=36±7 nm, VTE=36±8 nm and bare silicon=0.4±0.1 nm). Grazing incidence XRD diffraction patterns collected for the VPD and VTE films show peaks that can be assigned to the hexagonal phase of Mg and the underlying Si substrate (FIG. 21). The pattern of peak intensities of the VPD film is similar to the expected powder pattern, indicating that the Mg crystallites are randomly arranged on the substrate during film growth. In contrast, the VTE film shows the 002 peak is markedly higher intensity than expected from the powder pattern indicating a preferred alignment of the Mg crystallites with the (002) planes parallel to the substrate. Further, the response from the silicon lattice plane is attenuated in the XRD data from the VTE film, indicating denser packing than the VPD film. However, with appropriate modifications of the deposition conditions (substrate temperature, chamber pressure and carrier gas flow rates), the VPD method should lead to films with identical crystal patterns to those made using VTE.

Four-point probe resistivity measurements were carried out to examine the electrical properties of the metal films. Resistivities of 1.8×10⁻⁷ Ω-m and 8.4×10⁻⁸ Ω-m were obtained for VPD and VTE Mg films, respectively. The observed higher resistivity of films made using VPD can be attributed to grain boundaries, which were more pronounced in VPD metal films, and a looser packing/growth of the crystallites during deposition, which can enhance air/water diffusion and thus rapid oxidation of the film. The latter, associated with crystal orientation of grains (crystallographic orientation), is known to play a role in the oxidation properties of metals, e.g., Mg and copper, by directly impacting the atomic packing density and surface energy of the metals. Further, these metals were shown to exhibit lower surface energy (high atomic packing density) and a greater corrosion resistance, in solution (Mg) and thin films (Cu), under certain crystallographic orientations, e.g., 0001(Mg), 100(Cu) and 110(Cu). Regardless, while the resistivity is higher for films made using VPD, the value is still low enough to make it suitable for use as a cathode/anode in organic devices. Similarly, Zn films fabricated in the VPD system and deposited on silicon substrates show complete substrate coverage, but a rougher surface morphology than Mg films (RMS=77±3 nm), a resistivity of 4.6×10⁻⁶ Ω-m and XRD pattern peaks that can be assigned to various crystal planes of the hexagonal phase of Zn.

Organic Light-Emitting Devices with Magnesium Cathodes

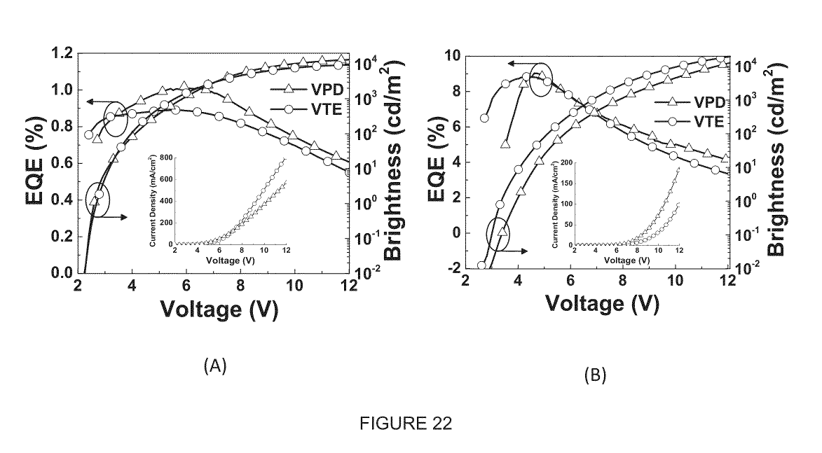

For purposes of comparison, fluorescent and phosphorescent OLEDs with Mg as the cathode were produced using either the VPD process described herein or existing VTE techniques. The deposition rates used in both methods for organics and metals were 1-4 Å/s and 4-8 Å/s, respectively. The fabrication of devices using the VPD system was done at a substrate holder temperature of 40-45° C. for organics and 20-25° C. for metals and total carrier gas flow rates of 60 sccm. As shown in FIG. 22a, fluorescent OLEDs (ITO/NPD (40 nm)/Alq₃ (40 nm)) made in the VPD with 200 nm Mg cathodes exhibited similar turn-on voltages (Vₒₙ=2.7 V at 1 cd/m²) and external quantum efficiencies (EQE=0.9±0.1% at 100 cd/m²) compared to fluorescent OLEDs made using VTE. As shown in FIG. 22b, phosphorescent devices (ITO/NPD (40 nm)/CBP-Ir(ppy)₃ 7 wt % (30 nm)/BCP (10 nm)/Alq₃ (40 nm)) made in the VPD had a higher turn-on voltage than devices made in the VTE (Vₒₙ at 1 cd/m²=4.1 and 3.3 V, respectively). A lower efficiency was observed for devices made in the VPD than for those made in the VTE (EQE=7.6±0.6 and 8.3±0.5% at 100 cd/m², respectively). The efficiencies of fluorescent and phosphorescent devices were comparable to values previously reported for devices with the same architecture used here (EQE=0.6-1.3% and EQE=7.5-8.5% at 100 cd/m², respectively). The current density vs voltage plots of OLEDs made by VPD and VTE are similar, which suggests that the small differences in turn-on voltage and EQE between PHOLED devices made using the two techniques may be due to exposure to air for approximately 5 minutes during exchange of source boats, electrode mask placement, and cleaning of the shutters. Fluorescent and phosphorescent devices fabricated in the VPD exhibited analogous electroluminescence spectra to devices made in the VTE, due to Alq₃ and Ir(ppy)₃ emission, respectively.

### Organic Photovoltaic Devices

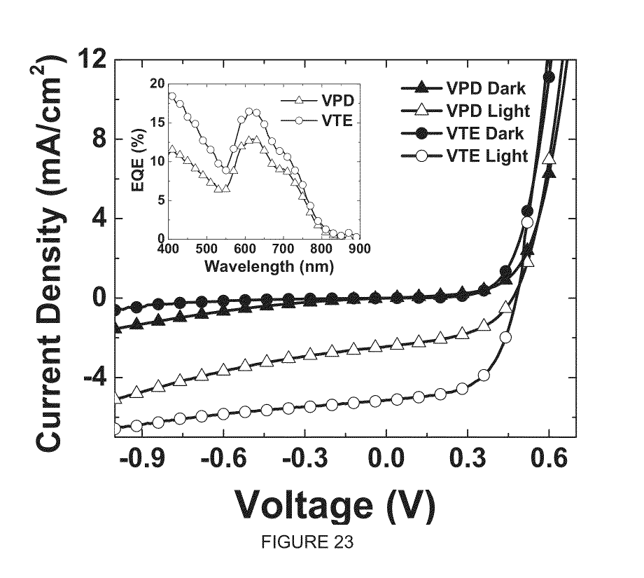

Organic photovoltaic devices using 200 nm thick Mg cathodes were produced using the VPD process described herein, and OPV devices using 200 nm thick Mg cathodes produced using existing VTE techniques were produced for purposes of comparison. Organic materials and metals were deposited at rates ranging from 1 to 4 Å/s and 4 to 8 Å/s, respectively. Devices prepared with the VPD system used substrate holder temperatures of 60-65° C. for organic materials and 20-25° C. for metals and total carrier gas flow rates of 60 sccm were used for both organics and metals. OPVs were initially fabricated on indium tin oxide (ITO) using CuPc (40 nm)/C₆ (40 nm) and the most common material, bathocuproine (BCP, 10 nm) as a buffer layer. While it has been established that BCP is an effective buffer when aluminum is used as a cathode in the same structure, non-rectifying current-voltage (IV) curves were obtained for analogous devices with Mg cathodes. Likewise, devices fabricated without a buffer layer exhibited poor charge extraction (ηₚ=0.16±0.05%). Poor contact of the metal cathode with the acceptor layer was observed with this device structure. However, working OPVs were obtained when a 10 nm buffer layer of 3,4,9,10 perylenetetracarbonyl bisbenzimidazole (PTCBI) was employed in the device. Current-voltage curves and efficiency-wavelength characteristics for the devices are shown in FIG. 23. OPVs with Mg cathodes fabricated in the VTE system had efficiencies comparable to values obtained for devices using the same CuPc-C60 architecture (ηₚ=0.75-1.3%) and an aluminum cathode. Devices made by either deposition method exhibited similar open circuit voltages (V_{oc}=0.45±0.06%) and fill factors (FF=0.50±0.06%). However, devices made using VPD displayed a lower current (J_{sc}=2.2±0.2 mA/cm²) than those produced using VTE (J_{sc}=4.6±0.4 mA/cm²). This resulted in a lower power efficiency (ηₚ=0.5±0.1%).

The decrease in current density from devices made using VPD can be ascribed to exposure to air (˜5 min) during electrode mask placement and cleaning of the shutters. To corroborate this hypothesis, a device was made in the VTE system where the organic films were exposed to air (˜5 min) prior to deposition of the electrode. A reference device was concurrently prepared where organic films were not subject to air during fabrication. Devices exposed to air displayed lower current density (10%) and a ˜25% decrease in efficiency, compared to the control device. Thus, it should be possible to correct the lower current density values for the devices produced using VPD by eliminating the exposure to air.

In summary, a new low vacuum method to deposit thin metal films using a vapor phase deposition (VPD) system has been demonstrated. Characterization of Mg and Zn films via SEM, AFM, XRD, and four-point probe resistivity indicate thin metal films fabricated in the VPD and VTE systems show complete substrate coverage and have comparable roughness/uniformity, crystallinity, and electrical conductivity.

By adequately controlling deposition conditions and substrate temperatures, a VPD system was used to deposit Mg cathodes for optoelectronics devices. Using these techniques it was possible to successfully fabricated fluorescent and phosphorescent OLEDs and OPVs with Mg cathodes, which perform similarly to those prepared by VTE. The new method allows complete fabrication of optoelectronic devices at system pressures greater than 1 torr (e.g., 1-10 torr). Further, low pumping times and high material utilization in the VPD system unlocks the opportunity to compete with high-volume, high-vacuum production systems for the manufacturing of optoelectronic devices. Deposition of metals with higher sublimation temperatures than magnesium and zinc (e.g., aluminum and silver) in the VPD system should also be feasible. The primary issues to address for these higher sublimation temperature metals are (i) vessel stability (i.e., use quartz or stainless steel instead of borosilicate glass), and (ii) adequate substrate cooling (≦50° C.) to prevent damage to the organic films.

### Study 2

### Evaluation and Preparation Details

The following discussion provides additional details regarding the techniques used to gather the data in FIGS. 19-23, as well as, production of the samples that were evaluated.

### Characterization of Metal Films

Profilometer profiles were obtained with a Sloan Dektak IIA stylus profilometer. Analysis of the Mg thin film profile showed that the 200 nm fabricated film deposited by VPD was soft, leaving a scratch mark during measurement, and had a thickness between 160 nm and 180 nm. In addition, profiles were acquired for 200 nm Mg thin films deposited in the VTE system. Metal film morphology, roughness, crystallinity and resistivity was characterized using a JEOL JSM-7001F scanning electron microscope (SEM), Digital Instruments Dimension 3100 atomic force microscopy (AFM), Rigaku Ultima IV powder/thin film diffractometer (XRD) and a Signatone 4-point probe resistivity head connected to a Keithley power source meter model 2400. XRD measurements were performed at 4 degrees per minute, 0.1 step, 0.3 degrees gamma and a 10 mm slit.

### OLED and OPV Substrate Preparation

Patterned ITO substrates with a resistivity of 1:20±5 ohms/sq and an ITO thickness of 2000±50 Å were used for OLEDs and OPVs made in both the VPD and VTE systems. OLED substrates were prepared/cleaned by scrubbing them with Tergitol NP-9 (Sigma-Aldrich Co.)/DI solution followed by a thorough rinse with DI water. The substrates were then rinsed with acetone (Sigma-Aldrich Co.), followed by a blow drying step with N₂ gas. The substrates were then placed for 10 min in a ultra-violet ozone cleaning system, model T10X10/OES. The substrates were then transferred to either the VPD or VTE systems for device fabrication.

OPV substrates were prepared/cleaned by scrubbing them with Tergitol NP-9 (Sigma-Aldrich Co.)/DI solution followed by a thorough rinse with DI water. The substrates were then rinsed with acetone (Sigma-Aldrich Co.), followed by a blow drying step with N₂ gas. The substrates were then washed with tetrachloroethylene (J.T. Baker), acetone (Macron Chemical), and ethyl alcohol anhydrous reagent (J.T. Baker). The wash consists of placing the substrates, in the order mentioned above, inside a beaker with each solvent for 10 min while heating the solvent to its boiling point. After washing, the substrates were blow dried with N₂ gas and placed in a ultra-violet ozone cleaning system, model T10X10/OES, for 10 min. Substrates were then transferred to either the VPD or VTE systems for device fabrication.

### OLED and OPV Device Structure

Fluorescent and phosphorescent OLED devices were made in both the VPD and VTE systems. The green fluorescent emitter device included N,N′-Di-[(1-naphthyl)-N,N′-diphenyl]-1,1′-biphenyl)-4,4′-diamine (NPD-40 nm), aluminum tris-(8 hydroxyquinoline) [Alq₃-40 nm] and Mg (Mg-200 nm). The Green phosphor emitter device consists of N,N′-Di-[(1-naphthyl)-N,N′-diphenyl]-1,1′-biphenyl)-4,4′-diamine (NPD-40 nm), fac-tris(2-phenylpyridine)iridium (Ir(ppy)₃) doped into 4,4′-Bis(N-carbazolyl)-1,1′-biphenyl (CBP-30 nm) @7% wt, Bathocuproine (BCP-10 nm), aluminum tris-(8 hydroxyquinoline) [Alq₃-40 nm] and Mg (Mg-200 nm).

Organic photovoltaic devices were also made in both the VPD and VTE system. The OPV device structure included copper phthalocyanine (CuPC-40 nm), fullerene (C₆₀-40 nm), 3,4,9,10 perylenetetracarboxylic bisbenzimidazole (PTCBI-10 nm), and magnesium (Mg-200 nm). The organic materials NPD, CBP and Alq₃ were obtained from Universal Display Corporation, BCP was purchased from MER corporation, fac-tris(2-phenylpyridine)iridium (Ir(ppy)₃) was synthesized according to literature, and both the fullerene (C₆₀) and magnesium chips (Mg) were purchased from Sigma-Aldrich Co. All organic materials were purified at least once via vacuum-train sublimation prior to use in the VPD or VTE systems.

### VPD Device Fabrication

A general schematic of the VPD setup can be seen in FIG. 4, in which the VPD 4″ Pyrex tube/reactor is housed in a Carbolite TVS 12/600/2416CG three zone Zones B-D) tube furnace. Preheating of the 4″ Pyrex tube (Zone A) is performed with a 4″×4″ 120 volt, 1100 watt Watlow mineral insulated band heater. The temperatures of the source boats, mineral insulated band heater and substrate holder was measured and controlled with Omega type K thermocouple probes attached to Omega CN76000 temperature controllers. Flow of inert gas (N₂) for each individual source boat, four in total, was measured using individual MKS mass flow controllers (0-500 sccm), while pressure was measured with a 10 torr Model 626A Baratron Pressure Transducer and adjusted using a MKS Model 153D Smart Downstream Throttle Valve. All MKS instruments were monitored and controlled with a MKS Model 647C flow channel controller box while vacuum was achieved with a Varian IDP-3 Oil Free Dry Scroll Pump.

The substrate holder, which was made out of aluminum and positioned approximately 1″ away from zone D, was designed to hold two 1″×1″ patterned substrates. The substrate holder had two shutters, which were utilized to control total thickness deposited onto each individual substrate. The substrate holder was cooled using N₂ gas that was passed through a copper coil submerged in liquid nitrogen. The substrate holder temperature was controlled by adjusting the flow/volume of cold N₂ gas by means of a needle valve. Material thickness was measured using a 6 MHz Inficon quartz monitor gold coated crystal sensor attached to an Inficon XTC/2 thin film deposition controller. Proper calibration of the Inficon crystal sensor was achieved using spectroscopic ellipsometry performed with a J.A. Woollam Co., Inc., VASE variable-angle ellipsometer with a VB-200 control module, and a CVI instruments Digikrom 242 monochroimator with a 75 W xenon light source to ensure accurate thickness of the metal films. The Inficon crystal sensor was kept at 15° C. at all times using a VWR 1140A chiller.

By introducing the source boat into the hot zone, the organic or metal was evaporated into the inert gas stream (N₂) which carried the organic compound to the cooled substrate where the organic or metal condensed onto the surface of the substrate. Organic and metal compounds were deposited at a constant pressure of 1 torr, total gas flow rates of 60 sccm and deposition rates of 1-4 Å/s and 4-8 Å/s, respectively. High and low sublimation temperature gradients utilized in the VPD can be seen in Table 4.

TABLE 4
Temperature gradient conditions for low/high
sublimation materials in the VPD system

| Low sublimation | | | High sublimation | | |
|---|---|---|---|---|---|
| temperature materials | | | temperature materials | | |
| Zone D | Pre-Substrate | 300° C. | Zone D | Pre-Substrate | 450° C. |
| | Zone | | | Zone | |
| Zone C | Hot Zone | 350° C. | Zone C | Hot Zone | 550° C. |
| Zone B | Hot Zone | 350° C. | Zone B | Hot Zone | 550° C. |
| Zone A | Pre-Heating | 350° C. | Zone A | Pre-Heating | 550° C. |
| | Zone | | | Zone | |

Because the VPD system only had four source boats, during the fabrication of phosphorescent devices two source boats, Alq₃ and Mg, were exchanged for NPD and BCP in order to complete the device. Further, VPD organic films were exposed to air for approximately 5 minutes during exchange of source boats and metal mask placement. The substrate holder temperature during deposition of NPD, Alq₃, and metals was between 40-45° C., while CuPc, C₆₀ and PTCBI depositions occurred at a substrate holder temperature of 60-65° C. Organic/metal sublimation temperatures during deposition are shown in Table 5.

TABLE 5
Sublimation temperature conditions of
organics/metals in the VPD system

| Compound | Sublimation temperature (° C.) |
|---|---|
| NPD | 260-270 |
| Alq₃ | 290-300 |
| CuPc | 440-480 |
| C₆₀ | 500-530 |
| PTCBI | 500-530 |
| Zn | 430-520 |
| Mg | 510-550 |

### VTE Device Fabrication

Comparative devices were made in an EvoVac 800 VTE deposition system attached to a glove box, and Inficon SQS-242 deposition software was used to control deposited material thicknesses using a 6 MHz Inficon quartz monitor gold coated crystal sensor. All films deposited in the VTE were performed at pressures ≦4×10⁻⁴ Pa, and with deposition rates ranging between 1-5 Å/s. Because the VTE system was attached to a glove box, organic films were never exposed to ambient air. Proper calibration of the Inficon crystal sensor via spectroscopic ellipsometry was performed using a J.A. Woollam Co., Inc., VASE variable-angle ellipsometer with a VB-200 control module and a CVI instruments Digikrom 242 monochromator with a 75 W xenon light source to ensure accurate thickness of films made.

### OLED and OPV Testing

OLED current-power and current-voltage curves, under applied forward bias of 0-12V, were measured using a Keithley power source meter model 2400, a Newport multi-function optical meter model 1835-C, a low power Newport silicon photodiode sensor model 818-UV, and a fiber bundle (used to direct the light into the photodiode). The silicon diode was set to measure power/photons at an energy of 520 nm, which was later corrected, during data processing, to the average electroluminescence wavelength of each individual device. Electroluminescence of OLEDs was collected with a photon technology international QuantaMaster model C-60 fluorimeter at several voltages, between 3-11 V, to ensure emission characteristics remained constant.

OPV current density (J) as a function of applied voltage (V) characteristics were measured in air at room temperature, in the dark and under spectral mismatch corrected 100 mW/cm², as well as, white light illumination from an AM-1.5G filtered 300 W Xenon arc lamp (Newport Inc.), and a Keithley power source meter model 2635A. Routine spectral mismatch correction for ASTM G173-03 was performed using a filtered silicon photodiode calibrated by the National Renewable Energy Laboratory (NREL) to reduce measurement errors. Frequency modulated monochromatic light (250 Hz, 10 nm FWHM) and lock-in detection was used to perform all spectral responsivity and spectral-mismatch correction measurement.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A method of depositing a film of a metallic material having a volatilization temperature higher than 350° C. from a source material, comprising:
providing the source material in a vacuum deposition processing chamber, the vacuum deposition processing chamber having an internal pressure;
providing a substrate in the vacuum deposition processing chamber, the substrate being maintained at a substrate temperature that is lower than the volatilization temperature and being spaced apart from, but in fluid communication with, said source material;
reducing an internal pressure of the vacuum deposition processing chamber to a pressure between 0.1 and 14,000 pascals;
volatilizing the source material into a volatilized metal by heating the source material to a first temperature that is higher than the volatilization temperature; and
transporting said volatilized metal to said substrate using a heated carrier gas, whereby the volatilized metal deposits on the substrate and forms said film.

2. The method of claim 1, wherein said source material comprises a metal selected from the group consisting of calcium, cadmium, magnesium, zinc, antimony, bismuth, indium, manganese, silver, aluminum, tin, lead, and alloys thereof.

3. The method of claim 1, wherein said source material consists of a metal.

4. The method of claim 1, wherein said source material is Mg or Zn.

5. The method of claim 1, wherein said substrate temperature is a temperature in the range of −100° C. to 200° C.

6. The method of claim 1, wherein said substrate temperature is a temperature in the range of −40° C. to 140° C.

7. The method of claim 1, wherein walls of said vacuum deposition processing chamber comprise borosilicate glass or fused silica.

8. The method of claim 1, further comprising heating walls of said vacuum deposition chamber.

9. The method of claim 1, wherein said vacuum deposition chamber comprises a first zone and a second zone, wherein said second zone is closer to the substrate than the first zone, the method further comprising maintaining said first zone at the first temperature, which is higher than a second zone temperature of said second zone.

10. The method of claim 9, wherein said substrate is located in said second zone and said source material is located in said first zone.

11. The method of claim 10, wherein said vacuum deposition chamber further comprises an intermediate zone between said first and second zone, wherein said intermediate zone is maintained as a temperature between the first zone temperature and the second zone temperature.

12. The method of claim 1, wherein said volatilizing is not ion assisted.

13. The method of claim 1, wherein a flow rate of said carrier gas is at least 1 standard cubic centimeters per minute.

14. The method of claim 1, wherein a rate of deposition on said substrate is at least 0.1 Å per second.

15. A method of depositing a film of a metallic material having a volatilization temperature higher than 350° C. from a source material, comprising:
providing the source material in a vacuum deposition processing chamber, the vacuum deposition processing chamber having an internal pressure;
providing a substrate in the vacuum deposition processing chamber, the substrate being maintained at a substrate temperature that is lower than the volatilization temperature and being spaced apart from, but in fluid communication with, said source material;
reducing an internal pressure of the vacuum deposition processing chamber to a pressure between 0.1 and 14,000 pascals;
volatilizing the source material into a volatilized metal by heating the source material to a first temperature that is higher than the volatilization temperature; and
transporting said volatilized metal to said substrate using a heated carrier gas, whereby the volatilized metal deposits on the substrate and forms said film,
wherein said source material comprises a material selected from the group consisting of calcium, cadmium, magnesium, zinc, antimony, bismuth, indium, manganese, silver, aluminum, tin, lead, and a fullerene, and
wherein said substrate temperature is a temperature in the range of −100° C. to 200° C.

16. A composite material comprising:
a substrate having an upper surface;
a metal coating over said upper surface, wherein said metal coating is formed from a source material by a method comprising:
providing the source material in a vacuum deposition processing chamber, the vacuum deposition processing chamber having an internal pressure, the source material consisting of a metallic material having a volatilization temperature higher than 350° C.;
providing a substrate in the vacuum deposition processing chamber, the substrate being maintained at a substrate temperature that is lower than the volatilization temperature and being spaced apart from, but in fluid communication with, said source material;
reducing an internal pressure of the vacuum deposition processing chamber to a pressure between 0.1 and 14,000 pascals;
volatilizing the source material into a volatilized metal by heating the source material to a first temperature that is higher than the volatilization temperature; and
transporting said volatilized metal to said substrate using a heated carrier gas, whereby the volatilized metal deposits on the substrate and forms said film.

17. The composite material of claim 16, further comprising an emissive layer coated over said upper surface, wherein said emissive layer comprises an organic electroluminescent compound and a host.

18. The composite material of claim 16, wherein said metallic material comprises a metal selected from the group consisting of calcium, cadmium, magnesium, zinc, antimony, bismuth, indium, manganese, silver, aluminum, tin, lead, and alloys thereof.

19. The composite material of claim 18, wherein said coating is an electrode.

20. The composite material of claim 16, wherein said substrate temperature is a temperature in the range of −100° C. to 200° C.
